(19) United States
(12) Patent Application Publication
(10) Pub. No.: US 2025/0297113 A1
(43) Pub. Date: Sep. 25, 2025

(54) THERMALLY CONDUCTIVE FILM AND METHOD

(71) Applicant: Sumitomo Chemical Co., Ltd, Tokyo (JP)

(72) Inventors: Tom FLETCHER, Godmanchester (GB); Przemyslaw GAWEL, Godmanchester (GB)

(73) Assignee: Sumitomo Chemical Co., Ltd, Tokyo (JP)

(21) Appl. No.: 18/852,980

(22) PCT Filed: Mar. 29, 2023
(86) PCT No.: PCT/EP2023/058214

§ 371 Date: Sep. 30, 2024

(30) Foreign Application Priority Data
Mar. 30, 2022 (GB) 2204605.6

(51) Int. Cl. C09D 5/18; C08G 69/32; C09D 177/06; H01L 23/29; H01L 23/373

(52) U.S. Cl. CPC C09D 5/18; C08G 69/32; C09D 177/06; H01L 23/293; H01L 23/3737

(57) ABSTRACT

A method of forming a product comprising a first component, a second component and a thermal transfer layer disposed between the first component and second component wherein the thermal transfer layer comprises a conjugated polymer; the thermal transfer layer is electrically insulating; and formation of the thermal transfer layer comprises application of a formulation comprising the conjugated polymer in dissolved form onto a surface of the first component or the second component.

### BACKGROUND

Thermally conductive materials are used in a wide variety of applications.

Mary Liu and Wusheng Yin, “A novel high thermal conductive underfill for flip chip application” http://yincae.com/assets/wp-1000-03_2013.pdf discloses an underfill containing diamond powder.

Huang et al, “Thermal conductivity of polymers and polymer nanocomposites”, Materials Science and Engineering: R: Reports, Vol. 132, October 2018, p. 1-22 describes thermal transport mechanisms in polymers.

Suematsu et al, “Polyimine, a C═N Double Bond Containing Polymers: Synthesis and Properties” Polymer Journal, Vol. 15, No. I, pp 71-79 (1983) discloses a polyimine of formula:

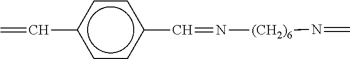

### SUMMARY

In some embodiments, the present disclosure provides a method of forming a product comprising a first component, a second component and a thermal transfer layer disposed between the first component and second component. The thermal transfer layer comprises a conjugated polymer. The thermal transfer layer is electrically insulating. Formation of the thermal transfer layer comprises application of a formulation comprising the conjugated polymer in dissolved form onto a surface of the first component or the second component.

The thermal transfer layer is preferably a homogenous layer extending across an area between the first component and second component.

Preferably, the product is an electronic device or electronic apparatus.

Preferably, when, in use, a temperature gradient exists between the first component and the second component.

In some embodiments, one of the first and second components is a heat sink.

In some embodiments, the product is a flip chip and the thermal transfer layer is an underfill of the flip chip.

Optionally, the conjugated polymer has a weight average molecular weight of at least 1×10⁴.

Optionally, the conjugated polymer comprises a repeating structure of formula (I):

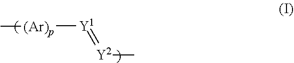

wherein Ar in each occurrence is an arylene or heteroarylene group; p is at least 1; and either one of Y¹ and Y² is CR¹ wherein R¹ is H or a substituent and the other of Y¹ and Y² is N, or each of Y¹ and Y² is CR¹.

Optionally, p is 2-5.

Optionally, each Ar of (Ar)p is independently selected from para-phenylene, thiophene, furan, and benzobisoxazole, each of which may independently be unsubstituted or substituted with one or more substituents.

Optionally, one or more Ar groups of (Ar)p are substituted with one or more substituents selected from substituents R² wherein R² in each occurrence is independently selected from:

F:

CN;

NO₂;

OH;

branched, linear or cyclic C₁₋₄₀ alkyl, preferably C₁₋₂₀ alkyl wherein one or more non-adjacent C-atoms may be replaced with O, S, NR⁵, SiR⁶₂, C═O or COO; wherein R⁵ in each occurrence is H or a substituent, preferably H or a C₁₋₂₀ hydrocarbyl group and R⁶ in each occurrence is independently a substituent, optionally a C₁₋₂₀ hydrocarbyl group; or an aryl or heteroaryl group Ar⁵ which is unsubstituted or substituted with one or more substituents, optionally phenyl which is unsubstituted or substituted with one or more substituents selected from F, CN, NO₂ and branched, linear or cyclic C₁₋₂₀ alkyl wherein one or more non-adjacent C-atoms may be replaced with O, S, NR⁵, SiR⁶₂, C═O or COO.

Optionally, L is selected from O, S, NR⁵ or a C₁₋₁₂ alkylene group wherein one or more non-adjacent C atoms may be replaced with O, S, NR⁵, SiR⁶₂, CO or COO wherein R⁵ in each occurrence is H or a substituent and R⁶ in each occurrence is independently a substituent.

Optionally, the repeating structure of formula (I) is comprised in a repeating group of formula (II), (III) or (IV).

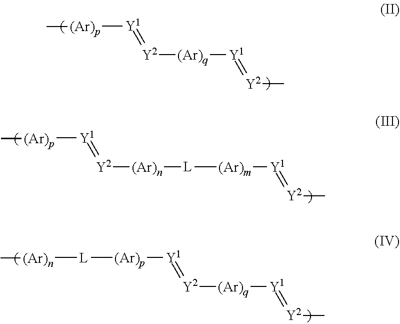

wherein:

q is at least 1;

n is 0 or a positive integer;

m is 0 or a positive integer; and

L is as described herein.

### DESCRIPTION OF DRAWINGS

FIG. 1 schematically illustrates an electronic device according to some embodiments comprising a flip-chip electrically connected to a substrate;

FIG. 2A schematically illustrates a method according to some embodiments of forming the electronic device of FIG. 1 in which an underfill layer is formed between the substrate and the flip-chip;

FIG. 2B schematically illustrates a method according to some embodiments of forming the electronic device of FIG. 1 in which a non-conducting film is applied to the flip chip prior to connection to the substrate;

FIG. 3 schematically illustrates a 3D chip stack according to some embodiments;

FIG. 4 schematically illustrates a substrate for measurement of thermal conductivity of a film; and

FIGS. 5A and 5B schematically illustrate apparatus for measurement of thermal conductivity including the substrate of FIG. 4.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list. References to a layer “over” another layer when used in this application means that the layers may be in direct contact or one or more intervening layers may be present. References to a layer “on” another layer when used in this application means that the layers are in direct contact.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

The present inventors have found that a high thermal conductivity may be provided by a film comprising or consisting of a conjugated polymer deposited from a solution of the conjugated polymer. Surprisingly, conjugated polymer films formed in this way have been found to possess higher thermal conductivity than films formed by deposition of monomers for forming the polymer followed by in-situ polymerisation of the monomers.

By “conjugated polymer” as used herein is meant a polymer comprising repeat units containing or consisting of conjugated groups which are directly linked and conjugated to conjugated groups of adjacent repeat units. The conjugated polymer may contain a repeat unit which forms a break in conjugation along the polymer backbone, e.g. a break provided by a C₁₋₁₂ alkylene group in which one or more non-adjacent C atoms of a C₂₋₁₂ alkylene chain may be replaced by O, S, CO or COO.

The conjugated polymer may comprise repeat units selected from one or more of arylene, heteroarylene, arylene vinylene, heteroarylene vinylene, arylene imine and heteroarylene imine repeat units.

Arylene groups as described herein are preferably selected from C₆₋₃₀ arylene group. Exemplary arylene repeat units are phenylene, biphenylene, terphenylene, fluorene, indenofluorene, naphthalene, anthracene and phenanthrene.

Arylene, heteroarylene, vinylene and imine groups as described herein may independently be unsubstituted or substituted with one or more substituents. Where present, substituents may be selected from:

F;

CN;

NO₂;

OH;

branched, linear or cyclic C₁₋₄₀ alkyl, preferably C₁₋₂₀ alkyl wherein one or more non-adjacent C-atoms may be replaced with O, S, NR⁵, SiR⁶₂, C═O or COO; wherein R⁵ in each occurrence is H or a substituent, preferably H or a C₁₋₂₀ hydrocarbyl group and R⁶ in each occurrence is independently a substituent, optionally a C₁₋₂₀ hydrocarbyl group; or an aryl or heteroaryl group Ar⁵, optionally phenyl, which is unsubstituted or substituted with one or more substituents which is unsubstituted or substituted with one or more substituents selected from F, CN, NO₂ and branched, linear or cyclic C₁₋₂₀ alkyl wherein one or more non-adjacent C-atoms may be replaced with O, S, NR⁵, SiR⁶₂, C═O or COO.

Optionally, the polymer comprises a repeating structure of formula (I):

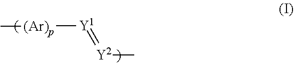

wherein Ar in each occurrence is an arylene or heteroarylene group; p is at least 1; and either one of Y¹ and Y² is CR¹ wherein R¹ is H or a substituent; and the other of Y¹ and Y² is N, or each of Y¹ and Y² is CR¹.

Preferably, p is at least 2, optionally 2-5. The extended rigid-rod type structure of formula (I) may enhance thermal conductivity of such a polymer as compared to the case where p=1.

Optionally, thermal conductivity of polymers as described herein is at least 0.15 Wm⁻¹K⁻¹, optionally at least 0.2 or 0.3 Wm⁻¹K⁻¹.

Ar in each occurrence in (Ar)p where p is greater than 1 may be the same or different, preferably the same.

Exemplary Ar groups include, without limitation, para-phenylene, thiophene, furan, and benzobisoxazole, each of which may independently be unsubstituted or substituted with one or more substituents. Para-phenylene is preferred.

Exemplary groups (Ar)p include, without limitation, groups of formulae (Va)-(Vc):

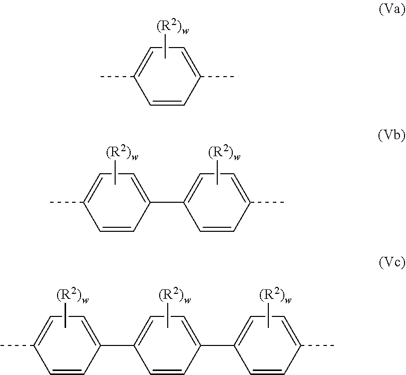

wherein R² independently in each occurrence is a substituent and w in each occurrence is independently 0 or a positive integer.

A preferred group (Ar)p has formula (Vc-1):

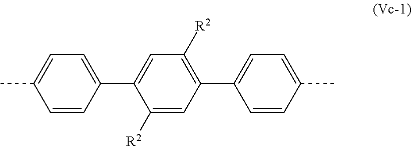

R¹ is preferably H or a C₁₋₂₀ hydrocarbyl group, more preferably H.

A C₁₋₂₀ hydrocarbyl group as described anywhere herein is preferably selected from C₁₋₂₀ alkyl; unsubstituted phenyl; and phenyl substituted with one or more C₁₋₁₂ alkyl groups.

Optionally, one or more Ar groups of (Ar)p are substituted with one or more substituents R². Preferably, R² in each occurrence is independently selected from:

F;

CN;

NO₂;

branched, linear or cyclic C₁₋₄₀ alkyl, preferably C₁₋₂₀ alkyl wherein one or more non-adjacent C-atoms may be replaced with O, S, NR⁵, SiR⁶₂, C═O or COO; wherein R⁵ in each occurrence is H or a substituent, preferably H or a C₁₋₂₀ hydrocarbyl group and R⁶ in each occurrence is independently a substituent, optionally a C₁₋₂₀ hydrocarbyl group; or

an aryl or heteroaryl group Ar⁵ which is unsubstituted or substituted with one or more substituents, optionally phenyl which is unsubstituted or substituted with one or more substituents selected from F, CN, NO₂ and branched, linear or cyclic C₁₋₂₀ alkyl wherein one or more non-adjacent C-atoms may be replaced with O, S, NR⁵, SiR⁶₂, C═O or COO.

Preferably, at least one substituent R², optionally each substituent R², is C₁₋₂₀ alkyl, C₁₋₂₀ alkoxy, or a group of formula —(Ak⁻¹)_{y}—(OCH₂CH₂)_{z}—Ak² wherein Ak¹ is a C₁₋₄ alkylene group;

y is 0 or 1; z is 1-15; and Ak² is a C₁₋₄ alkyl group. More preferably, R² is a C₁₋₁₂ alkyl or C₁₋₁₂ alkoxy. C₁₋₁₂ alkoxy is particularly preferred.

The polymer may comprise a divalent linker group L disposed in the polymer backbone, wherein L is selected from O, S, NR⁵ or a C₁₋₁₂ alkylene group wherein one or more non-adjacent C atoms of a C₂₋₁₂ alkylene group may be replaced with O, S, NR⁵, SiR⁶₂, CO or COO.

In some embodiments, the divalent linker group L is disposed between and linked directly to two Ar groups.

In some embodiments, the divalent linker group L is disposed between and linked directly to an Ar group and an imine (—C(R¹)═N—) group.

In some embodiments, the divalent linker group L is disposed between and linked directly to two imine (—C(R¹)═N—) groups.

The polymer may be formed by polymerising a monomer or monomers having reactive groups which react to form an imine. The repeating structure of formula (I) may be part of a larger repeat unit of the polymer formed by polymerising the monomer or monomers. Exemplary repeat units include, without limitation, formulae (II)-(IV):

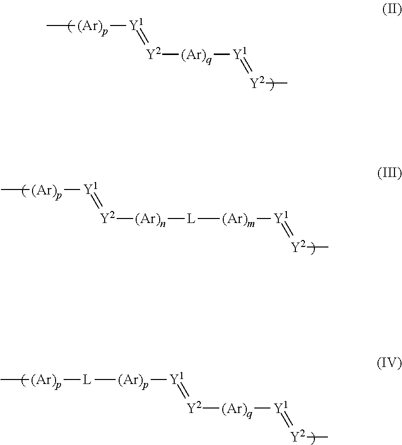

wherein Ar, p, Y¹, Y² and L are as described above;

q is at least 1, preferably 1-5, more preferably 1-3;

n is 0 or a positive integer, preferably 0 or 1-5, more preferably 0, 1, 2 or 3; and

m is 0 or a positive integer, preferably 0 or 1-5, more preferably 0, 1, 2 or 3.

If q is greater than 1 then each Ar of (Ar)q, may be the same or different, preferably the same.

If n is greater than 1 then each Ar of (Ar)n, may be the same or different, preferably the same.

If m is greater than 1 then each Ar of (Ar)m, may be the same or different, preferably the same.

Preferred Ar groups of (Ar)q, (Ar)m and (Ar)m are as described with reference to (Ar)p.

The repeat units of the polymer may be the same or different. In some embodiments, the polymer contains a mixture of different repeat units of formulae (II)-(IV). The polymer may contain one or more of: different repeat units of formula (II); different repeat units of formula (III); different repeat units of formula (IV); and a repeat unit selected from one of formulae (II)-(IV) and at least one other repeat unit selected from another of formulae (II)-(IV). In a preferred embodiment, the polymer contains a repeat unit without a divalent linker group L and a repeat unit with a divalent linker group L, for example a repeat unit of formula (II) and a repeat unit of formula (III).

In the case where n and m are each 0, the repeat unit of formula (III) has formula (IIIa):

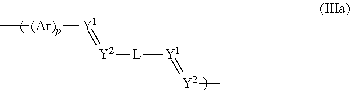

The polymers may be substituted with groups for bonding together of polymer chains, e.g. hydrogen bonding or covalent bonding, to enhance long-range ordering of the polymers.

Polymers as described herein are preferably at least partially crystalline.

Polymers as described herein are preferably linear (i.e. unbranched) polymers in which the or each repeat unit of the polymer is divalent.

Polymers as described herein may undergo pi-pi stacking when deposited as a film.

The polystyrene-equivalent number-average molecular weight (Mn) measured by gel permeation chromatography of the polymers described herein may be in the range of about 1×10³ to 1×10⁸, and preferably 1×10⁴ to 5×10⁶. The polystyrene-equivalent weight-average molecular weight (Mw) of the polymers described herein may be 1×10³ to 1×10⁸, and preferably 1×10⁴ to 1×10⁷.

The present inventors have found that higher thermal conductivity may be achieved at a higher weight-average molecular weight. The Mw of the polymer is preferably at least 1×10⁴, more preferably at least 2×10⁴. Optionally, the Mw of the polymer is up to 1×10⁶ or 1×10⁷.

In the case of a multimodal polymer, Mw as described herein is for the highest Mw peak in the polymer's GPC.

### Additional Components

The conjugated polymer film may consist of the conjugated polymer or may comprise one or more further materials, optionally one or more amorphous polymers, e.g. polystyrene, polyethylene or polypropylene; and/or one or more thermally conductive materials, for example fillers such as boron nitride, aluminium oxide and/or aluminium nitride. The thermally conductive filler preferably has a thermal conductivity >10 W/m.K. Optionally, the thermally conductive filler is electrically non-conductive. Depending on the application of the film, the thermally conductive filler may be electrically insulating, e.g. with an electrical conductivity of no more than 1×10⁻⁸ S/m, optionally 1×10⁻⁹ S/m or 1×10⁻¹⁰ S/m.

### Polymerisation

Conjugated polymers in which there is a direct bond between aromatic carbon atoms of adjacent repeat units may be formed by polymerisation of monomers in which aromatic carbon atoms are substituted with leaving groups which leave upon polymerisation of the monomers to form conjugated repeat units. Exemplary polymerization methods of this type include, without limitation, Yamamoto polymerization as described in, for example, T. Yamamoto, “Electrically Conducting And Thermally Stable pi-Conjugated Poly(arylene)s Prepared by Organometallic Processes”, Progress in Polymer Science 1993, 17, 1153-1205, the contents of which are incorporated herein by reference and Suzuki polymerization as described in, for example, WO 00/53656, WO 2003/035796, and U.S. Pat. No. 5,777,070, the contents of which are incorporated herein by reference.

Conjugated polymers may be formed by polymerising a monomer or monomers having reactive groups which react to form an imine.

In some embodiments, imine-containing polymers as described herein are formed by polymerisation of a first monomer comprising a group of formula (I) and two reactive groups X¹ with a second monomer comprising two reactive groups X² wherein one of X¹ and X² is a group of formula —C(═O)R¹ and the other of X¹ and X² is NH₂.

Optionally according to these embodiments, the first monomer is selected from formulae (M1-A)-(M1-B) and and the second monomer is selected from formulae (M2-A) and (M2-B):

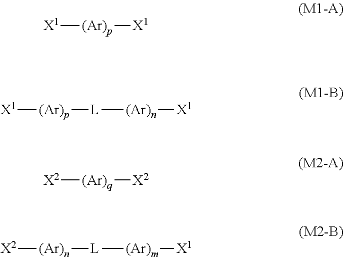

In some embodiments, only one monomer substituted with X¹ groups and only one monomer substituted with X² groups are reacted. It will be understood that the polymer formed from these monomers will contain only one repeat unit structure.

In some embodiments, two or more different monomers substituted with X¹ groups and/or two or more different monomers substituted with X² groups are reacted. It will be understood that the polymer formed from these monomers will contain two or more different repeat unit structures.

In some embodiments, a polymer comprising a repeating structure of formula (I) may be formed by polymerisation of a monomer of formula (M3):

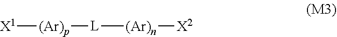

In some embodiments, only one monomer of formula (M3) is reacted. It will be understood that the polymer formed from this monomer will contain only one repeat unit structure.

In some embodiments, two or more different monomers of formula (M3) are reacted. It will be understood that the polymer formed from these monomers will contain two or more different repeat unit structures.

The reaction between X¹ and X² may be catalysed by a Lewis acid. The Lewis acid may or may not be a Bronsted-Lowry acid.

Exemplary catalysts include, without limitation, sulfonic acids and salts thereof, for example p-toluene sulfonic acid; triflic acid; and salts thereof. An exemplary triflic acid salt is scandium triflate, Sc(Trf)₃. The catalyst may be provided in an amount of 0.01-0.3 molar equivalents of the total number of moles of the monomer or monomers.

### Formulations

Formation of a film comprising a conjugated polymer as described herein comprises deposition of a formulation comprising the polymer dissolved or dispersed in a liquid, preferably dissolved in the liquid, onto a surface followed by evaporation of the liquid.

The concentration of dissolved polymer in the formulation is optionally in the range of 1-100 mg/ml, preferably 10-50 mg/ml.

The liquid may be one or more solvents selected from, without limitation, benzene or naphthalene substituted with one or more substituents, optionally one or more substituents selected from C₁₋₁₂alkyl, C₁₋₁₂alkoxy, F and Cl; ethers; esters; halogenated alkanes; ketones; sulfoxides; and mixtures thereof. Exemplary solvents include, without limitation, halogenated benzenes, for example benzene with one or more Cl substituents such as o-dichlorobenzene; xylenes, 1,2,4-trimethylbenzene, mesitylene, 1-methylnaphthalene, 1-chloronaphthalene, diiodomethane, anisole, N-methylpyrrolidone, 1,2-dimethoxybenzene, dimethylsulfoxide 1,3-dimethyl-2-imidazolidinone and cyclopentanone.

The formulation may be deposited by any suitable solution deposition technique including, without limitation, spin-coating, dip-coating, drop-casting, spray coating and blade coating.

The formulation may be allowed to dry at ambient temperature and pressure or it may be subjected to heat and/or vacuum treatment following deposition in order to remove the solvent, for example thermal annealing (at atmospheric pressure or under vacuum), solvent vapour annealing or a hot press or calendaring process

In some embodiments, the formulation comprises thermally conductive particles dispersed therein.

In some embodiments, the formulation does not comprise any thermally conductive particles, such as boron nitride.

Optionally, a film comprising or consisting of a polymer as described herein has a thickness in the range of 1-100 microns, preferably 10-100 microns.

### Applications

A film comprising a polymer as described herein may be used in any known application of a thermally conductive film.

The film as described herein may be disposed between a surface of a heat-generating device and a heat transfer device configured to transfer heat away from the heat-generating device, such as in any known thermal interface management application.

It will be understood that in this arrangement the film is configured to transfer heat from the heat-generating device to the heat transfer device. The film preferably has a first surface in direct contact with a surface of the heat-generating device and/or a second surface opposing the first surface in direct contact with a surface of the heat transfer device.

The heat-generating device may be an electronic device.

The thermally conductive film is electrically insulating, i.e. in use the film does not provide an electrical conduction path between any electrically conductive surfaces that it may be in contact with. Optionally, the thermally conductive film has an electrical conductivity of no more than 1×10⁻⁸ S/m, optionally 1×10⁻⁹ S/m or 1×10⁻¹⁰ S/m.

In some embodiments, e.g. where the thermally conductive film is disposed on a surface of a heat sink, the thermally conductive film is electrically isolated. By “electrically isolated” is meant that the thermally conductive film is not electrically connected, directly or through any electrically conductive surface that it may be in contact with, to an electrical power source.

Any passive or active heat transfer device known to the skilled person may be used including, without limitation, a heat sink having a surface in contact with the film and an opposing surface comprising one or more heat-dissipating features, for example fins or a pipe or channel configured to transfer heat to a fluid flowing through the pipe or channel. The fluid may or may not undergo a phase change upon absorption of heat.

Preferably, the film is a thermally conductive layer of an electronic device or apparatus.

In some embodiments, a film as described herein may be disposed on a surface of a heat sink opposing a surface of the heat sink having fins extending therefrom. In use, the film may be disposed between the heat sink and an electrical component.

A film as described herein may be a heat spreader layer disposed on a surface of a printed circuit board, for example a PCB for use in LED arrays.

A film as described herein may be used as an electrically non-conductive film, e.g. an underfill, for a flip chip including but not limited to 3D stacked multi-chips. Such a film may help manage thermal strain in flip-chips.

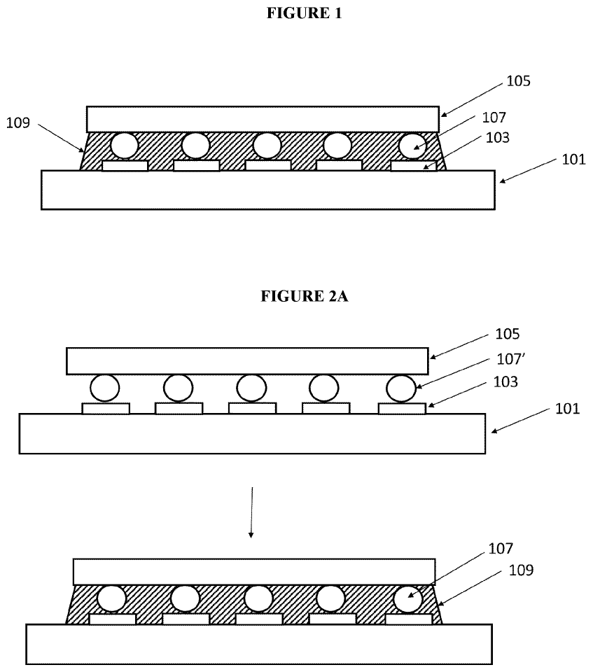

FIG. 1 illustrates an electronic device comprising a chip 105; a substrate 101, e.g. a printed circuit board; and electrically conductive interconnects 107 between electrically conductive pads 103 on the surface of the substrate 101 and the chip 105. Underfill 109 comprising or consisting of a polymer as described herein fills the region between the chip 105 and substrate 101. Optionally, the polymer is crosslinked.

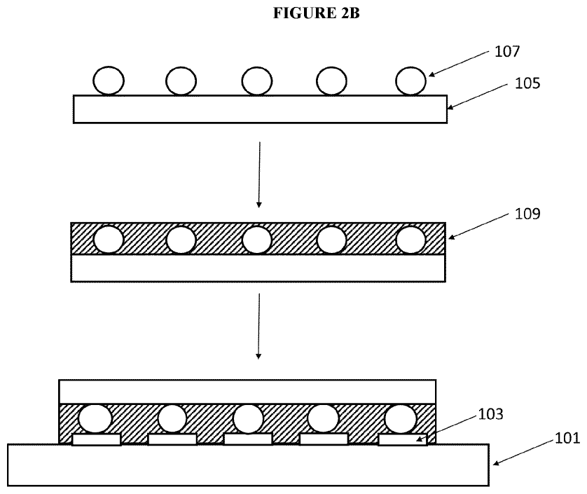

With reference to FIG. 2A, in some embodiments formation of an electronic device comprises bringing electrically conductive bumps 107′, e.g. solder bumps, into contact with electrically conductive pads 103 disposed on a substrate 101, e.g. a printed circuit board to form interconnects 107 from electrically conductive bumps 107′. Formation of underfill 109 comprising a polymer as described herein comprises application of a formulation comprising the monomer or monomers into the overlap region between the chip 105 and the substrate 101. Optionally, the polymer is crosslinked following application of the formulation and reaction of the monomer or monomers, e.g. by heat and/or UV treatment.

With reference to FIG. 2B, in some embodiments a polymer precursor film is formed over a surface of the chip 105 carrying electrically conductive bumps 107′. FIG. 4B illustrates complete coverage of the conductive bumps 107′ however it will be understood that the conductive bumps 107′ may be partially covered such that a part of the conductive bumps 107′ protrude from a surface of the film 109. The conductive bumps 107′ are then brought into contact with conductive pads 103 disposed on a substrate 101, e.g. a printed circuit board, to form electrically conductive interconnects between the substrate and the chip. Formation of the electrically conductive interconnects may comprise application of heat and/or pressure.

If the polymer of film 109 is crosslinked then crosslinking may take place before, during or after the conductive bumps 107′ are brought into contact with the conductive pads 103.

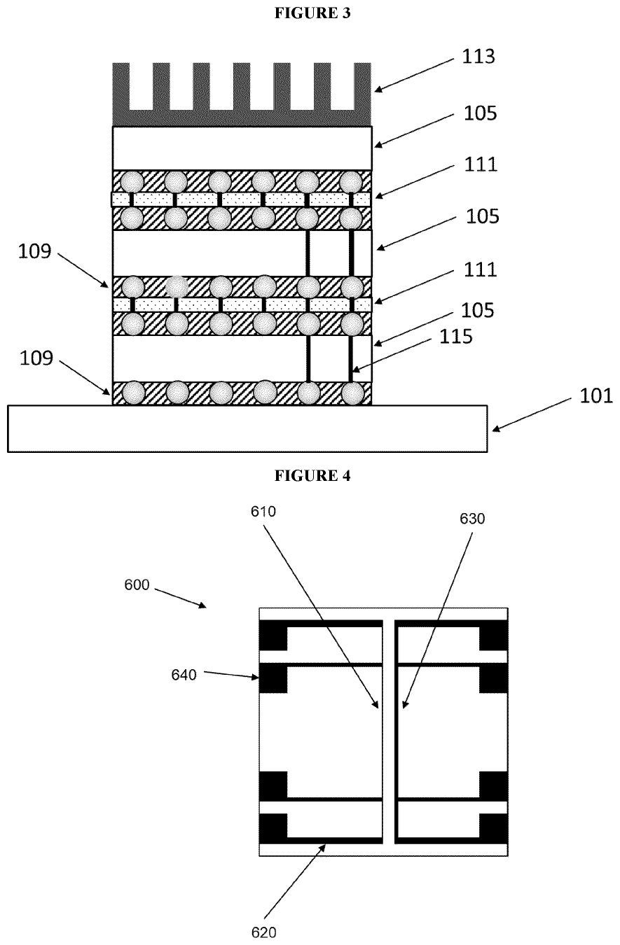

Two or more chips may be connected with a film comprising a polymer as described herein disposed between chips. FIG. 3 illustrates a 3D stack of chips 105 according to some embodiments, wherein the chips 105 are interposed by an interposer 111 and a non-electrically conductive film 109 disposed between adjacent interposer and chip surfaces and between the substrate 101, e.g. a printed circuit board, and a first chip of the 3D stack. At least one non-electrically conductive film 109 comprises a polymer as described herein. Through-vias 115 are formed through the chips 105 and the interposers. The 3D stack may comprise a heat sink 113 disposed on a surface thereof.

In some embodiments, a film comprising or consisting of a polymer as described herein may be disposed between an electronic device and a heat sink.

### EXAMPLES

### Polymer Example 1

Catalyst (p-toluenesulfonic acid) was added to a stirred solution of monomer A3 (1 eq) and monomer B3 (1.1 eq) in toluene (200 ml). The mixture was left to stir at room temperature for 72 hours. During this time a yellow precipitate (Precipitate A) formed, this was collected by filtration (Filtrate A). The precipitate (A) was then suspended in THF (500 ml), and the mixture was heated to 65° C. for several hours. The mixture was then filtered (under gravity) to remove any insoluble material. The filtrate was collected and set aside (Filtrate B). The insoluble material was collected, resuspended in more THF (500 ml) and the process repeated. This mixture was then filtered and the precipitate collected and washed with further THF (filtrate collected as Filtrate C). This precipitate consists of high MW materials, and cannot be dissolved. Yields vary from 100-300 mg.

Filtrates B and C were then concentrated to the limit of their solubility and then added dropwise to stirred methanol (600 ml). On addition, a fluffy yellow powder formed. This powder was collected by gravity filtration, and dried under vacuum overnight to give two fractions of differing MW ('Medium' fraction from Filtrate B, ‘Heavy’ fraction from Filtrate C). Yields of these fractions vary (100-300 mg). The filtrates (Filtrate D) were collected, and the solvent removed. The resulting solid was resuspended in a small volume of THF (20 ml) and precipitated into MeOH (100 ml). The precipitate was collected (‘Light’ fraction) by gravity filtration, and dried under vacuum overnight.

GPC on Filtrate A shows the presence of monomers and short chain oligomers.

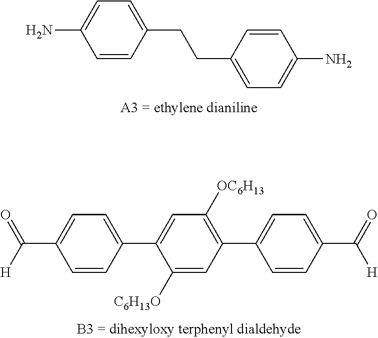

### Polymer Example 2

Polymer Example 2 was formed by the method described for Polymer Example 1 except that monomer B2 was used in place of monomer B3:

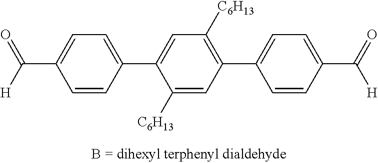

### Film Formation—Exemplary

A formulation was prepared by heating the polymer in o-dichlorobenzene at 95° C., typically to create a solution of concentration 20 mg/ml, although concentrations can range up to 40 mg/ml. A gasket prepared from 0.5 mm thick fluorosilicone rubber sheet (Silex Silicones Ltd) was applied to the substrate described below in order to contain the ink within a prescribed area (18×10 mm rectangle) of the substrate. The substrate with silicone gasket was pre-heated on a hotplate at 70° C. and the hot solution was drop cast onto the substrate. The substrate was then moved to a cold plate at room temperature and allowed to dry overnight. The hotplate temperature can range from 50° C. to 90° C., and the cold plate temperature can range from 10° C. to 60° C.).

### Film Formation-Comparative

For the purpose of comparison, films were formed by deposition of monomers as described above followed by polymerisation. This in-situ polymerisation was performed by either depositing a solution or a paste of the monomers followed by polymerisation. These polymerisation methods are referred to herein as, respectively, in-situ solution polymerisation and in-situ melt polymerisation.

For in-situ solution polymerisation, monomers were dissolved in the solvent at the same desired concentration (w/v) e.g. 10 mg/ml, optionally applying heat up to 80° C. to aid dissolution. The monomer inks were mixed by volume to produce an equimolar mixture of the monomers. A catalyst may be added by the same method of pre-dissolving and mixing by volume to achieve the desired molar ratio of catalyst to monomer. After mixing the ink is promptly dropcast onto a substrate described below for thermal conductivity measurement. A gasket prepared from 0.5 mm thick fluorosilicone rubber sheet (Silex Silicones Ltd) and applied to the substrate is used to contain the ink within a prescribed area (18×10 mm rectangle) for the dropcasting procedure. The wet film is dried by evaporation on a hotplate which may be at room temperature or any temperature below the solvent boiling point; for the examples in the table the drying temperature was consistently 50° C. After drying the gasket is removed and the film is optionally annealed at 170° C. for 2 hours.

For in-situ melt polymerisation, an equimolar ratio of the monomers were weighed into a mortar and a small amount of a non-solvent liquid, typically a water/alcohol blend, was added to act as grinding agent, and the mixture was ground into a paste using a pestle. Additional liquid was added in order to form a dispersion at a concentration of 20 mg/ml. After mixing the ink is promptly dropcast onto the substrate described below for thermal conductivity measurement. A gasket prepared from 0.5 mm thick fluorosilicone rubber sheet (Silex Silicones Ltd) and applied to the substrate is used to contain the ink within a prescribed area (18×10 mm rectangle) for the dropcasting procedure. The wet film is dried by evaporation on a hotplate set at a low temperature so as not to cause dissolution or reaction of the dispersed solids, for example 40° C. The substrate was then removed from the hotplate and transferred to a second hotplate preheated to 140° C. It can be observed that the monomers first melt to a liquid state, and then a polymeric film is formed returning the sample to a solid state. After this has taken place (within 5 minutes) the substrate is moved to a cooling station and the silicone gasket removed.

### Thermal Conductivity Measurement

A sensor substrate 600 (ca. 25 mm×25 mm) illustrated in FIG. 4 was used for measurement of thermal conductivity as described herein. The substrate has a polyethylene naphthalate (PEN) film (Dupont Teonex Q83, 25 μm) with a 200 nm thick heating structure consisting of a 20 micron wide heater line 610, 500 micron wide busbars 620 for application of a current and contact pads 640. A sensing structure mirrors the heating structure except that the heater line is replaced with a 200 micron wide sensor line 630.

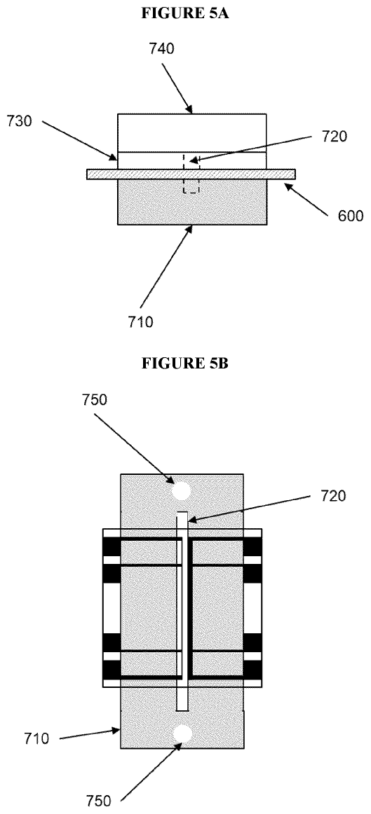

With reference to FIGS. 5A and 5B, the sensor substrate 600 carrying the film to be measured is placed on a temperature controlled aluminium block, regulated via a PID system such that the temperature may be controlled by software. The aluminium block has a long notch 720 of 1 mm width and ˜1 mm depth cut into it. The sensor substrate 600 is placed over the notch such that the central heater line 610 is aligned with the centre of the notch 720, and the sensor line 630 is aligned with the edge of the notch. A PMMA sheet 730 (2 mm thickness) with a notch cut-through matching that of the aluminium block 710 is placed over the top and an addition piece of plain PMMA sheet 740 (4 mm thickness) is placed on top to enclose the device. The entire assembly is clamped using bolts and nuts at positions 750. The heater line is connected to a sourcemeter unit (Keithley 2400) using a 4-wire measurement set up. The sensor line is connected to a multimeter unit (Keithley 2000) using a 4 wire set up.

The temperature of the assembly is first stabilised at a predetermined temperature. The resistance of the heater line and the temperature sensor is then measured. To measure the resistance of the heater line without causing undue heating a low current is sourced and voltage measured in short pulses, with time allowed between pulses for heat to be dissipated. A constant DC current is then passed along the heater line to cause resistive heating. The arrangement of the substrate in the assembly causes heat to flow through the substrate and film to the aluminium block which acts as a heat sink, setting up an approximate one-dimensional steady state heat flux. The power dissipated in the heater line, and the resistance of the heater line and temperature sensor is additionally measured in this state. This process is repeated for increasing sourced current, and the complete process repeated at the next temperature setpoint.

The resistances of the heater line and sensor lines under the condition of no heat flux at different temperature setpoints are used as calibration data in a straight-line fit of resistance and temperature, allowing the temperature of the resistive elements to be determined under the condition of steady state heat flux. As such the temperature gradient, AT, between the heater line and temperature sensor (aligned with the heatsink) can then be calculated. The power dissipated in the heater line is assumed to be completely converted to heat energy Q. A straight line fit is then made between dT and Q with additional parameters for the length of the heater line over which power is measured (L, 14.4 mm), the distance between the voltage sense points) and the gap width (2 w, 1 mm). This provides a measure of the conductance C of the device under test and is affected by losses pertaining to conductive heat transfer in the substrate and convective and radiative heat transfer to the environment (h).

To calculate a thermal conductivity κ, the same measurement process is carried out on substrates without any test film (substrate only). We assume the losses will be approximately the same when measuring a coated vs uncoated substrate. We subtract the conductance of the substrate (C_{S}) from the device measurement (C_{F+S}) to adjust for these losses. The thermal conductivity (k_{F}) is then calculated by dividing the resulting film only conductance by the film thickness (d_{F}). The film thickness is determined using a digital micrometer by measuring the total thickness and subtracting the substrate thickness.

$$C = \frac{Q w}{2 L Δ T} = κ d + 2 h {w}^{2} {κ}_{F} = \frac{{C}_{F + S} - {C}_{S}}{{d}_{F}}$$

As set out in Table 1, films formed by solution deposition of preformed polymers showed significantly higher thermal conductivity than films formed by either in-situ solution polymerisation or in-situ melt polymerisation.

TABLE 1

| | Thermal Conductivity (Wm⁻¹K⁻¹) | | |
|---|---|---|---|
| | | In-situ - | In-situ - |
| Monomers | Pre-polymerised | solution | melt processing |
| A3 + B2 | 0.40 | 0.32 | — |
| A3 + B3 | 0.65 | 0.50 | 0.28 |

Light, medium and heavy fractions of Polymer Example 1 were deposited onto a substrate as described above and their thermal conductivities were measured. Results are set out in Table 2.

In Table 2, the aldehyde/imine ratio is an indicator of molecular weight in which aldehyde absorption is attributed to unreacted aldehyde end groups of the polymer and imine absorption is attributed to imine groups of repeat units of the polymer. A lower aldehyde/imine ratio is therefore indicative of a higher molecular weight.

The weight-average molecular weights given in Table 2 are for the highest Mw peak in the polymer's GPC.

GPC was performed using an Agilent GPC 50 with refractive index detection with stabilised THF as the mobile phase flowing at 1 ml/min, and the column oven set at 40° C. The apparatus was used with an Agilent AS-RT Autosampler and Agilent Data Stream.

The instrument was calibrated using a series of polystyrene standard materials dissolved in stabilised THF. 100 microlitres of each standard, in turn, was injected onto the columns and will have a characteristic response (i.e. retention time) relative to the size of molecule injected. The response for each standard is analysed using the instrument software to produce a calibration curve.

Unknown samples were then dissolved in stabilised THF, 100 microlitres were injected onto the columns and the software was used to determine the molecular weight against the calibration. The results obtained are relative to the polystyrene standards used.

TABLE 2

| | Mw (from | Aldehyde/Imine IR | Thermal Conductivity |
|---|---|---|---|
| Fraction | GPC) | stretching ratio | (W/mK) |
| ‘Light’ | 23947 | 1.03 | 0.32 |
| ‘Medium’ | 40847 | 0.27 | 0.57 |
| ‘Heavy’ | 56399 | 0.11 | 0.61 |

1. A method of forming a product comprising a first component, a second component and a thermal transfer layer disposed between the first component and second component wherein the thermal transfer layer comprises a conjugated polymer; the thermal transfer layer is electrically insulating; and formation of the thermal transfer layer comprises application of a formulation comprising the conjugated polymer in dissolved form onto a surface of the first component or the second component.

2. A method according to claim 1 wherein the product is an electronic device or electronic apparatus.

3. A method according to claim 2 wherein, in use, a temperature gradient exists between the first component and the second component.

4. A method according to claim 2 wherein one of the first and second components is a heat sink.

5. A method according to claim 2 wherein the product is a flip chip and the thermal transfer layer is an underfill of the flip chip.

6. A method according to claim 1 wherein the conjugated polymer has a weight average molecular weight of at least 1×10⁴.

7. A method according to claim 1 wherein the conjugated polymer comprises a repeating structure of formula (I): 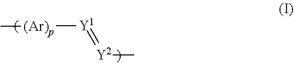
wherein Ar in each occurrence is an arylene or heteroarylene group; p is at least 1; and either one of Y¹ and Y² is CR¹ wherein R¹ is H or a substituent and the other of Y¹ and Y² is N, or each of Y¹ and Y² is CR¹.

8. The method according to claim 7 wherein p is 2-5.

9. The method according to claim 7 wherein each Ar of (Ar)p is independently selected from para-phenylene, thiophene, furan, and benzobisoxazole, each of which may independently be unsubstituted or substituted with one or more substituents.

10. The method according to claim 7 wherein one or more Ar groups of (Ar)p are substituted with one or more substituents selected from substituents R² wherein R² in each occurrence is independently selected from:
F;
CN;
NO₂;
OH;
branched, linear or cyclic C₁₋₄₀ alkyl, preferably C₁₋₂₀ alkyl wherein one or more non-adjacent C-atoms may be replaced with O, S, NR⁵, SiR⁶₂, C═O or COO; wherein R⁵ in each occurrence is H or a substituent, preferably H or a C₁₋₂₀ hydrocarbyl group and R⁶ in each occurrence is independently a substituent, optionally a C₁₋₂₀ hydrocarbyl group; or
an aryl or heteroaryl group Ar⁵ which is unsubstituted or substituted with one or more substituents, optionally phenyl which is unsubstituted or substituted with one or more substituents selected from F, CN, NO₂ and branched, linear or cyclic C₁₋₂₀ alkyl wherein one or more non-adjacent C-atoms may be replaced with O, S, NR⁵, SiR⁶₂, C═O or COO.

11. The method according to claim 7 wherein L is selected from O, S, NR⁵ or a C₁₋₁₂ alkylene group wherein one or more non-adjacent C atoms may be replaced with O, S, NR⁵, SiR⁶₂, CO or COO wherein R⁵ in each occurrence is H or a substituent and R⁶ in each occurrence is independently a substituent.

12. The method according to claim 7 wherein the repeating structure of formula (I) is comprised in a repeating group of formula (II), (III) or (IV). 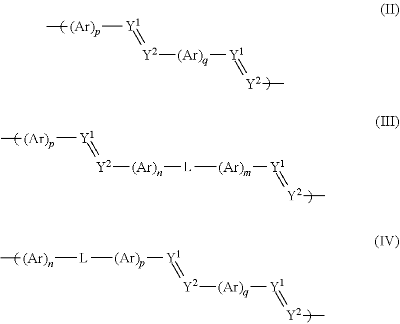
wherein:
q is at least 1;
n is 0 or a positive integer;
m is 0 or a positive integer; and
L is as defined in claim 7.
